(19) United States
(12) Patent Application Publication
(10) Pub. No.: US 2021/0025062 A1
(43) Pub. Date: Jan. 28, 2021

(54) PHOTOELECTROCHEMICAL DEVICE, MONOLITHIC WATER SPLITTING DEVICE AND METHODS OF PRODUCTION

(71) Applicant: KING ABDULLAH UNIVERSITY OF SCIENCE AND TECHNOLOGY, Thuwal (SA)

(72) Inventors: Jr-Hau HE, Thuwal (SA); Purushothaman VARADHAN, Thuwal (SA); Hui-Chun FU, Thuwal (SA)

(21) Appl. No.: 16/645,299

(22) PCT Filed: Oct. 25, 2018
(86) PCT No.: PCT/IB2018/058343

§ 371 Date: Mar. 6, 2020

Related U.S. Application Data
(60) Provisional application No. 62/582,468, filed on Nov. 7, 2017.
(60) Provisional application No. 62/689,569, filed on Jun. 25, 2018.

(51) Int. Cl. C25B 1/00; C25B 1/06; C25B 11/04; C25B 9/06

(52) U.S. Cl. CPC C25B 1/003; C25B 1/06; C25B 11/0405; C25B 9/06; C25B 11/0415; C25B 11/0478

(57) ABSTRACT

A photoelectrochemical device includes a substrate having a metallic electrocatalyst, a first ohmic contact layer arranged on the substrate, a tandem photoabsorber arranged on the first ohmic contact layer, a second ohmic contact layer arranged on the tandem photoabsorber, and a protective layer arranged on the second ohmic contact layer. The substrate is comprised of a different material than the tandem photoabsorber.

### CROSS-REFERENCE TO RELATED APPLICATIONS

This application claims priority to U.S. Provisional Patent Application No. 62/582,468, filed on Nov. 7, 2017, entitled “FLEXIBLE AND ABOVE 12% UNASSISTED SOLAR-TO-HYDROGEN EFFICIENT PHOTOELECTROCHEMICAL WATER-SPLITTING CELLS BASED ON TANDEM III-V PHOTOABSORBERS,” and U.S. Provisional Patent Application No. 62/689,569, filed on Jun. 25, 2018, entitled “PHOTOELECTROCHEMICAL DEVICE, MONOLITHIC WATER SPLITTING DEVICE AND METHODS OF PRODUCTION,” the disclosure of which is incorporated herein by reference in its entirety.

### BACKGROUND

### Technical Field

Embodiments of the disclosed subject matter generally relate to a photoelectrochemical device, a monolithic water splitting device and methods of production.

### Discussion of the Background

The desire to reduce pollution from conventional fossil fuel sources has led to an increasing reliance on so-called green energy conversion devices. Although solar cells are the main focus for light-based green energy research, storage of the energy generated by solar cells has been an ongoing concern because solar cells only generate energy when exposed to light, and thus are not able to generate energy at night and generate less energy during cloud cover.

Photoelectrochemical devices, such as photoabsorber-based devices, have been proposed for water splitting as an alternative to solar cells because the photoabsorber can generate hydrogen from water. The hydrogen can be much more easily stored than the energy generated by a solar cell, which typically requires large batteries. Further, hydrogen has a reasonable free energy content and there exists excellent hydrogen evolution electrocatalysts to convert the hydrogen into energy.

In order to overcome the thermodynamics of water splitting, conventional photoelectrochemical devices typically employ a tandem photoabsorber (also referred to as a two-photon photoabsorber) based on III-V materials. To avoid device performance degradation due to the strain of lattice mismatch, conventional photoelectrochemical devices are formed on a gallium arsenide (GaAs) or germanium (Ge) substrate, which are quite expensive, and thus the resulting device is not cost-effective. Techno-economical analysis shows that the substrate accounts for 76% of the cost of a conventional photoelectrochemical water splitting device. Further, the III-V materials used for the photoabsorber spontaneously photocorrode in the electrolytes that are typically employed, which leads to rapid deterioration of device performance and catastrophic failure of such devices.

Thus, it would be desirable to provide for a photoelectrochemical device and monolithic water splitting device that addresses the problems of the expensive substrate and corrosion in the electrolyte used to produce hydrogen.

### SUMMARY

According to an embodiment, there is photoelectrochemical device, which comprises a substrate comprising a metallic electrocatalyst, a first ohmic contact layer arranged on the substrate, a tandem photoabsorber arranged on the first ohmic contact layer, a second ohmic contact layer arranged on the tandem photoabsorber, and a protective layer arranged on the second ohmic contact layer. The substrate is comprised of a different material than the tandem photoabsorber.

According to another embodiment, there is a method, which comprises providing a tandem photoabsorber supported on a first side by a rigid substrate, forming a substrate on a second side of the tandem photoabsorber, removing the rigid substrate from the first side of the tandem photoabsorber, and forming a protective layer on the first side of the tandem photoabsorber.

According to a further embodiment, there is a monolithic water splitting device, which comprises a first metallic electrocatalyst, a metallic substrate arranged on the first metallic electrocatalyst, a first ohmic contact layer adjoining the metallic substrate, a tandem photoabsorber comprising group III and group V materials and adjoining the first metallic contact layer, a second ohmic contact layer adjoining the tandem photoabsorber, and a second metallic electrocatalyst adjoining the second ohmic contact layer.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1A is a schematic diagram of a photoelectrochemical device according to an embodiment;

FIG. 1B is a schematic diagram of a photoelectrochemical device according to an embodiment;

FIG. 1C is a schematic diagram of the photoelectrochemical process occurring in a photoelectrochemical device according to an embodiment;

FIG. 2 is a flowchart of a method for forming a photoelectrochemical device according to an embodiment;

FIGS. 3A-3D are schematic diagrams of a method for forming a photoelectrochemical device according to an embodiment;

FIG. 4 is a schematic diagram of a photoelectrochemical device according to an embodiment;

FIG. 5 is a graph of the current density versus potential for a photoelectrochemical device according to an embodiment;

FIG. 6 is a graph of the current density over time for a photoelectrochemical device measured at alkaline conditions according to an embodiment;

FIG. 7 is a graph of the collected hydrogen and oxygen gasses over time produced using a photoelectrochemical device according to an embodiment;

FIGS. 8A and 8B are graphs illustrating the performance of a photoelectrochemical device at different bending angles and number of bendings, respectively, according to an embodiment; and

FIGS. 9A and 9B are schematic diagrams of monolithic water splitting device according to an embodiment.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of photoelectrochemical devices.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

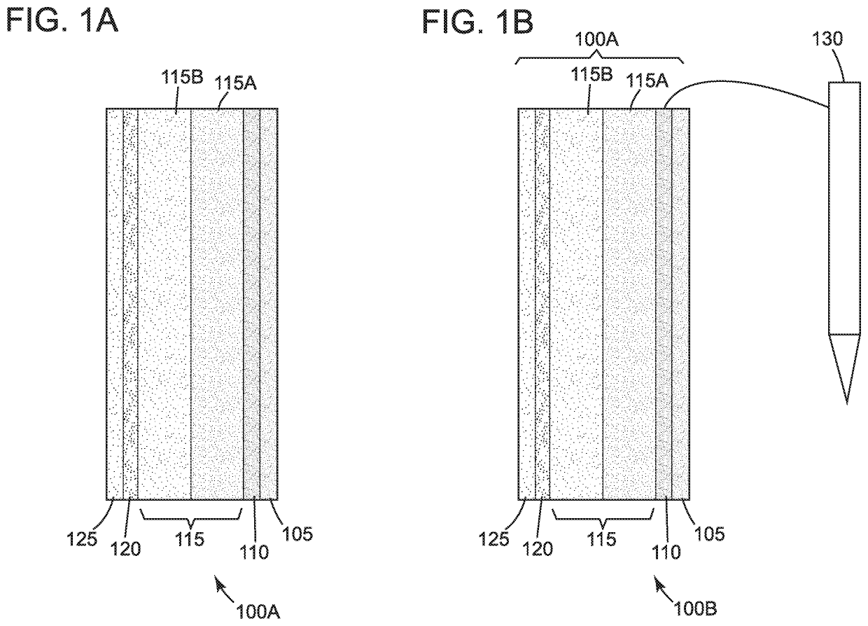

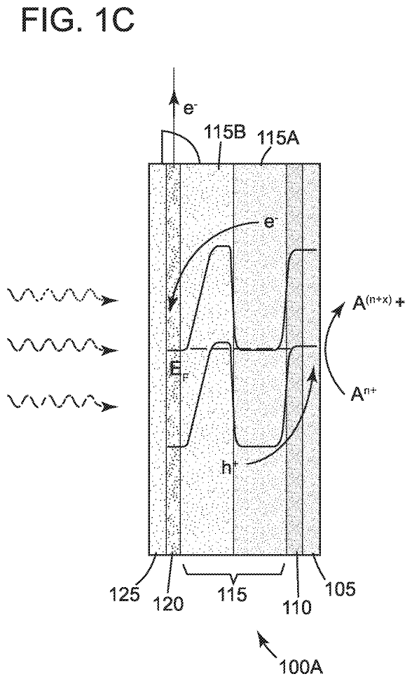

FIG. 1A is a schematic diagram of a photoelectrochemical device 100A. The photoelectrochemical device 100A includes a substrate 105 comprising a metallic electrocatalyst and a first ohmic contact layer 110 arranged on the substrate 105. A tandem photoabsorber 115 is arranged on the first ohmic contact layer 110 and a second ohmic contact layer 120 is arranged on the tandem photoabsorber 115. A protective layer 125 is arranged on the second ohmic contact layer 120. The substrate 105 is comprised of different material than the tandem photoabsorber 115.

In the illustrated embodiment, the material of the substrate 105 can be a metal or metal oxide, for example, nickel or nickel oxide, and the material of the tandem photoabsorber 115 includes, for example, gallium arsenide (GaAs) for layer 115A and indium gallium phosphide (InGaP) for layer 115B. Nickel is particularly advantageous because it not only serves as an ohmic contact but also serves as an integrated oxygen evolution reaction (OER) electrocatalyst. A tandem photoabsorber comprising an indium gallium phosphide layer on top of a gallium arsenide layer is particularly advantageous because it generates sufficient energy to perform unassisted water splitting (i.e., water splitting without the introduction of energy other than solar energy).

It should be recognized that the substrate 105 and tandem photoabsorber 115 can comprise materials other than those disclosed in this example. For example, the substrate 105 can comprise any metallic material that can protect the photoelectrochemical device 100A from the electrolyte in which it is submerged during operation, e.g., water. Similarly, one or both of the layers 115A and 115B of the tandem photoabsorber 115 can be silicon-based. One limitation on the materials for the tandem photoabsorber is that the combination of layers 115A and 115B produce enough energy to effect unassisted water splitting, which is considered to require approximately 1.9-2.2 V.

In an embodiment, the first ohmic contact layer 110 is a p-doped semiconductor layer and the second ohmic contact layer 120 is an n-doped semiconductor layer. Further, in an embodiment, the protective layer 125 can be, for example, glass. The protective layer can be made of any type of material that passes light while also protecting the photoelectrochemical device 100A from the electrolyte in which it is submerged during operation.

FIG. 1B is a schematic diagram of a photoelectrochemical device 100B. In the device 100B, device 100A is a photoanode, which is physically separate from and electrically coupled to a counter-electrode 130 via the second ohmic contact 110. The counter-electrode can be made of any material, for example platinum.

FIG. 1C is a schematic diagram of the photoelectrochemical process occurring in the photoelectrochemical device 100A. As illustrated, light enters the device 100A through protective layer 125 and passes into the second ohmic contact layer 120. The light then passes into the second photoabsorber layer 115B, which causes an electron-hole pair separation in both layers. Both the first 115A and second 115B photoabsorber layers are connected in series by a tunnel junction.

When the photoelectrochemical device 100A is illuminated, the first 115A and second 115B photoabsorber layers act as two diodes connected in series, and the carriers (electrons and holes) will separate and travel to their corresponding ends. Accordingly, the holes (h+) are collected in the substrate 105 (where the electrocatalysts are integrated) and carries out oxygen evolution reaction. Although not illustrated, the electrons flow through the first ohmic contact layer 110 to the counter electrode 130 in FIG. 1B where the reduction reaction occurs.

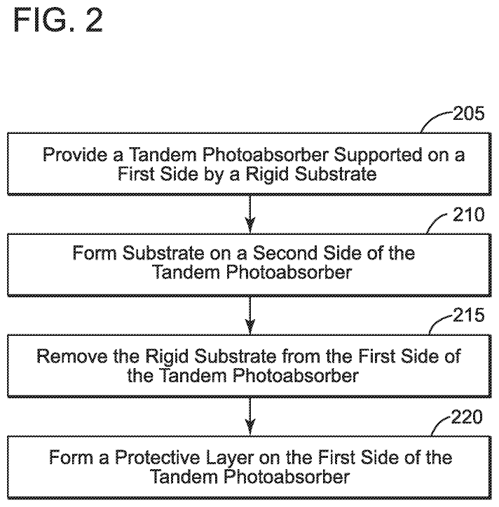

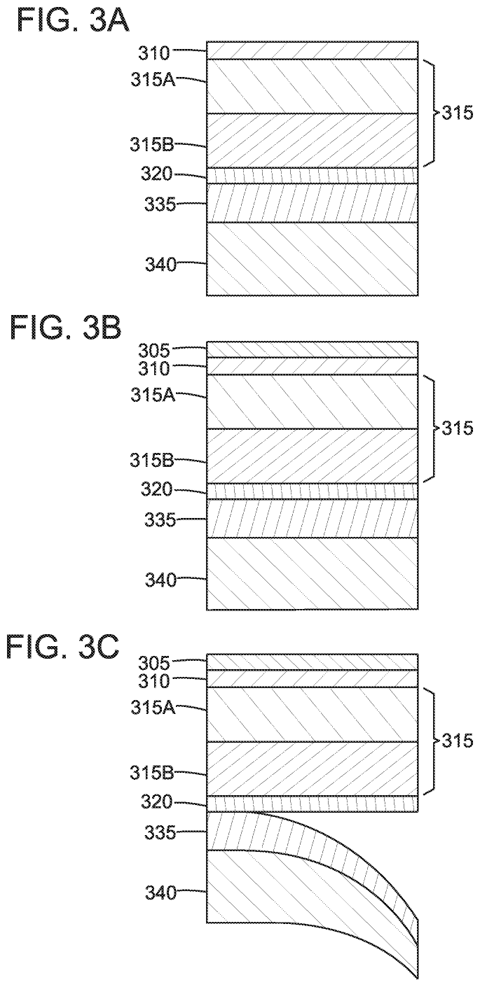

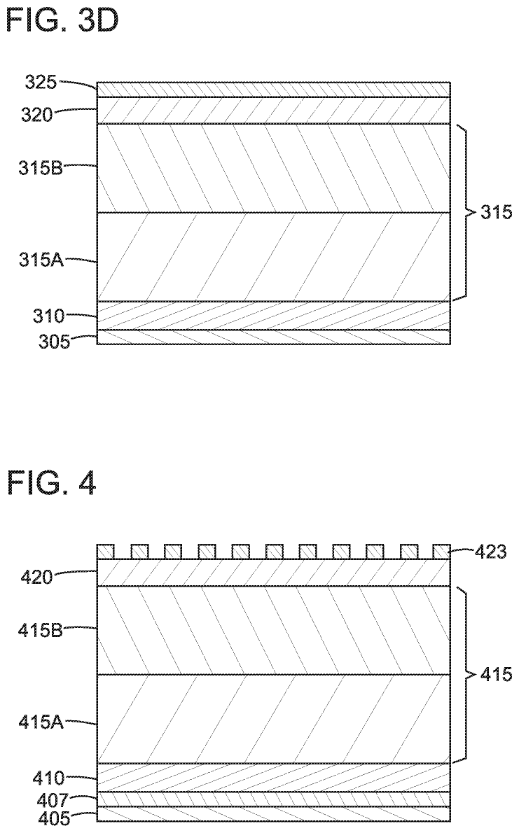

A method for forming the photoelectrochemical device will now be described in connection with FIGS. 2 and 3A-3D. Initially, a tandem photoabsorber 315 supported on a first side by a rigid substrate 340 is provided (step 205 and FIG. 3A). The tandem photoabsorber can be produced, for example, by epitaxial growth on a lattice matched or lattice mismatched substrate. In an embodiment, the layers of the tandem photoabsorber 315 and the rigid substrate 340 are comprised of a common material. In a non-limiting example, the common material is gallium, and the first photoabsorber layer 315A is comprised of gallium arsenide (GaAs), the second photoabsorber layer 315B is comprised of indium gallium phosphide (InGaP), and the rigid substrate 340 is comprised of p-doped gallium arsenide (p-GaAs). As illustrated, in an embodiment, a first ohmic contact layer 310 is arranged on top of the tandem photoabsorber 315, a second ohmic contact layer 320 is arranged on the bottom of the tandem photoabsorber 315, and an etching stop layer 335 is interposed between the tandem photoabsorber.

A substrate 305 is then formed on a second side of the tandem photoabsorber 315 (step 210 and FIG. 3B). This can be achieved, for example, by electrodeposition of a rigid and stable metal and/or metal oxide on top of the tandem photoabsorber 315. The substrate 305 can be an electrocatalytic substrate and can be rigid or flexible. In an embodiment, the substrate 305 is comprised of nickel, which can be, for example, electrodeposited with a thickness of 70-100 μm. However, the substrate 305 can comprise any metallic material that can protect the photoelectrochemical device 100A from the electrolyte in which it is submerged during operation and that also assists with a catalytic reaction with the electrolyte.

Next, the rigid substrate 340 is removed from the first side of the tandem photoabsorber 315 (step 215 and FIG. 3C). In an embodiment, this removal involves etching and removal (i.e., an epitaxial lift-off technique) of tandem photoabsorber 315 from the substrate 305. The substrate 305 can then be reused. Thus, the etching stop layer 335 protects the tandem photoabsorber 315 and second ohmic contact 320 from chemicals used during the epitaxial lift-off procedure. Specifically, this can involve separating, for example, the top 20 μm of the tandem junction 315 from the substrate 340 and then selectively etching any remaining film from the substrate 340 and any buffer layer to expose the second ohmic contact layer 320.

Finally, the device is flipped and a protective layer 325 is formed on the first side of the tandem photoabsorber 315 (step 220 and FIG. 3D). The protective layer that is deposited can include nickel, titanium, nickel alloys, titanium alloys, nickel oxides, or titanium oxides. Consistent with the discussion above in connection with FIGS. 1A and 1B, the photoelectrochemical device of FIG. 3D can be connected to a counter electrode. An anti-reflective coating can be deposited on top of the first ohmic contact 310 comprising, for example, silicon oxide (SiO₂ (n=1.42)) and titanium oxide (TiO₂ (n=2.32)). This method is particularly advantageous because the expensive substrate, which can be a gallium arsenide substrate in this example, is not part of the final device, and thus can be reused to form additional devices.

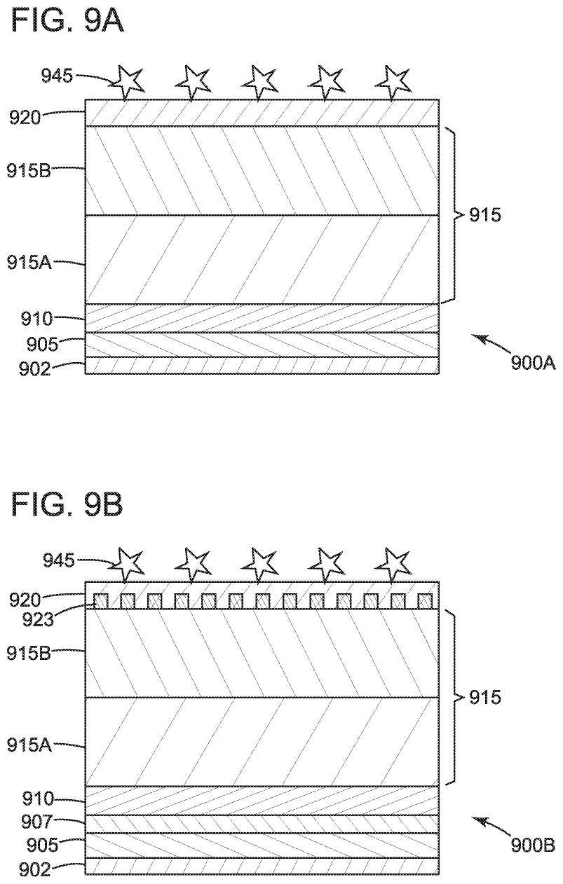

As will be discussed in more detail below in connection with FIGS. 9A and 9B, an electrocatalyst, such as a metallic electrocatalyst, can be formed on the outside surface of the substrate. This can be achieved, for example, by electrochemical or atomic layer deposition of a suitable electrocatalyst or suitable electrocatalysts. The formation of the electrocatalyst can be performed before or after the protective layer 325 is formed on the first side of the tandem photoabsorber 315 in step 220.

As will be appreciated from the discussion above, the substrate 105 acts as a stressor layer during the epitaxial lift-off process. The substrate 105 also acts as a back ohmic contact to from a buried junction configuration for the photoelectrochemical device, acts as a back reflector for photon recycling, and acts as an earth abundant oxygen evolution electrocatalyst.

It may be desirable to evaluate the performance of the photoelectrochemical device of FIG. 3D, in which case additional layers are provided on the device, which are illustrated in FIG. 4. Specifically, as illustrated in FIG. 4, a conductive layer 407 is interposed between the substrate 405 and the first ohmic contact layer 410 and finger electrode 423 is arranged on top of the second ohmic contact layer 420. The conductive layer 407 can be formed on the first ohmic contact layer 410 prior to forming the substrate 405 in step 210. In an embodiment, the conductive layer 407 can be, for example, gold-beryllium (AuBe) deposited by an electron beam. The finger electrode 423 can be formed after the rigid substrate is removed in step 215. In an embodiment, the finger electrode 423 can be, for example, gold (Au) deposited by an electron beam.

Various aspects of a photoelectrochemical device with a tandem photoabsorber having a top photoabsorber comprised of indium gallium phosphide (InGaP) and a bottom photoabsorber comprised of gallium arsenide (GaAs) were evaluated in which the active area of the device was 0.25 cm². Using simulated sunlight under a one sun illumination condition, the current density (Jsc) was 11.76 mA cm⁻², the open-circuit voltage (Voc) was 2.25 V, and the fill factor (FF) was 0.77. The photoelectrochemical device had a solar-to-current conversion efficiency of 18.36%. The indium gallium phosphide top photoabsorber had a maximum external quantum efficiency (EQE) of 78% and the gallium arsenide bottom photoabsorber had a maximum external quantum efficiency of 87%, which demonstrates that the indium gallium phosphide top photoabsorber is the current limiting factor of the device.

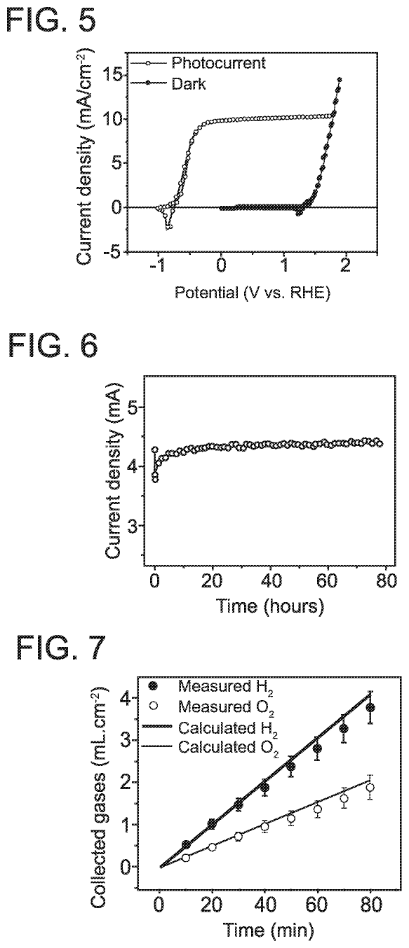

The photoelectrochemical device was also subjected to cyclic voltammetry (CV) evaluation without uncompensated resistance (iR) correction under an AM 1.5G standard illumination and a three electrode system in a 1.0 M KOH (aq) electrolyte and dark electrolysis of a nickel substrate 405 and second ohmic contact 420, the results of which are illustrated in FIG. 5. The three electrodes included the photoelectrochemical device as working electrode, a platinum counter electrode (such as electrode 130 illustrated in FIG. 1B), and a saturated calomel electrode (SEC) as a reference electrode. As illustrated, the cyclic voltammetry behavior with a Jsc (i.e., the short-circuit current) of 10.1 mA cm⁻² closely matches the photovoltaic performance expected of the device structure. During the cyclic voltammetry evaluation, the surface of the photoelectrochemical device was unchanged and no electrocatalyst deposits occurred during water oxidation.

The cyclic voltammetry evaluation also demonstrated that the photoelectrochemical device exhibited the following characteristics, Voc=2.05 V, fill factor=0.77, and Jsc=10.1 mA cm₋₂ (i.e., η=12.54%). The Voc of 2.05 V is ˜200 mV less than the expected value, which can be mainly attributed to electrolytic carrier losses and interfacial carrier recombination. The excellent values for Voc and Jsc can be attributed to the large area epitaxial lift-off technique employed to remove the photoelectrochemical device from the expensive substrate. More significantly, the Voc of the indium gallium phosphide/gallium arsenide tandem photoabsorber is optimized under the experimental conditions. Further, by forming a 50 μm thick nickel substrate on the device and removing it from a 350 μm thick gallium arsenide substrate, the overall weight of the photoelectrochemical device was reduced by 1 in 20.

The unassisted water splitting capability was evaluated in 1.0 M KOH(aq) by connecting a photoelectrochemical device having an active area of 0.25 cm² to a counter electrode having a ˜1.5 cm² platinum active area deposited on nickel foam. Linear sweep voltammetry (LSV) measurements showed a Jsc=9.8 mA cm⁻² with instantons gas formulation on both the photoelectrochemical device and the counter electrode, which indicates that unassisted water splitting was being performed. The measurements were used to directly calculate the solar-to-hydrogen conversion efficiency (STH) based on a solar-to-hydrogen η=(j_{H}_{₂}×1.23 V)/I, which translates into an efficiency of η=12.1% under the assumption of 100% Faradaic efficiency. The incident photon to current conversion efficiency (IPCE) for the tandem photoabsorber comprising indium gallium phosphide and gallium arsenide photo absorbers demonstrated that a maximum IPCE of 67% for the indium gallium phosphide top photoabsorber and 74% for the bottom gallium arsenide photoabsorber. Both values are expectedly less than their corresponding external quantum efficiency (EQE) values due to the water reflection and quartz reflection losses, losses due to reflections from the front glass protective layer, and losses from bubble formation during water splitting.

A critical requirement for any photoelectrochemical device is the ability to perform under any electrolytic or harsh pH conditions. The robustness of the photoelectrochemical cell over a wide range of pH was evaluated by measuring water oxidation using the following three electrolytes, alkaline (1 M KOH), neutral (1 M Na₂SO₄), and water obtained from the Red Sea (pH: 8.2) using the three electrode arrangement discussed above. The device exhibited a high Jsc of 10.1 mA/cm² in alkaline electrolyte and a high Jsc of 8.4 mAcm² in neutral electrolytes. Even when the Red Sea water (which mimics the natural water splitting) is used as an electrolyte, the photoelectrochemical device exhibits a Jsc of 7.2 mA/cm². These high Jsc values demonstrate an excellent solar driven water splitting over a wide range of pH conditions, which allows the device to be used in a wide variety of applications.

Those skilled in the art will recognize that photoelectrochemical devices having photoabsorbers comprising III-V materials, due to their weak chemical stability, have been shown to severely corrode under water splitting conditions, even when using neutral electrolytes. One attempt to address this is to employ an atomic layer deposited (ALD) titanium oxide (TiO₂) protective layer. This type of protective has been shown to leach into the electrolyte and there has been no demonstrated long-term stability over a period of months or years, which is a lifespan necessary for practical applications. In contrast, the disclosed photoelectrochemical device does not require an additional protection layer because the substrate 105, which acts as a stressor layer for the epitaxial lift-off procedure and as an electrocatalyst for oxygen evolution reaction, as serves as a protection layer.

In order to evaluate the stability of the disclosed photoelectrochemical device, the device continuous chronoamperometry of the photoelectrochemical device under one sun illumination in a 1.0 M KOH (aq) electrolyte was performed, the results of which are illustrated in FIG. 6. The tandem photoabsorber in this case was 0.25 cm² thick and the electrolyte was a neutral composition of 1M Na₂SO₄. The nickel substrate of the photoelectrochemical device was approximately 50 μm thick. In other embodiments, the nickel substrate can be thicker than 50 μm, such as when the substrate is intended to be rigid instead of flexible. As illustrated, the initial Jsc of the device remains relatively stable over a period of 80 hours, which indicates that the nickel substrate protected the tandem photoabsorber from degradation from the electrolyte. Long term operation of the photoelectrochemical device could lead to corrosion of the nickel substrate, which can result in leakage and damage to the light absorbing side. A nickel substrate thicker than the 50 μm thick nickel substrate in the tested photoelectrochemical device can be used to address the corrosion issues.

The performance of the disclosed photoelectrochemical device in a two-cell electrode setup during continuous chronoamperometry was also evaluated to determine the collected hydrogen and oxygen over time, the results of which are illustrated by the graph of FIG. 7. The active area of the tandem photoabsorber was 0.25 cm² and the active area of the platinum cathode was 1 cm². The gasses evolved from the photoanode 100A were collected using an airtight syringe and immediately evaluated using gas chromatography (GC). As illustrated, after eighty minutes of operation and collection time, the average volume of collected gasses (represented by the lines in the graph) were ˜0.81 μl/s of H₂ and ˜0.38 μl/s of O₂, which almost exactly matches the theoretically calculated H₂ and O₂ values (represented by the dots in the graph), which demonstrates a faradaic efficiency of over 95%. The almost 2:1 ratio of H₂ and O₂ indicates less photocorrosion of the active materials under the given photoelectrochemical conditions.

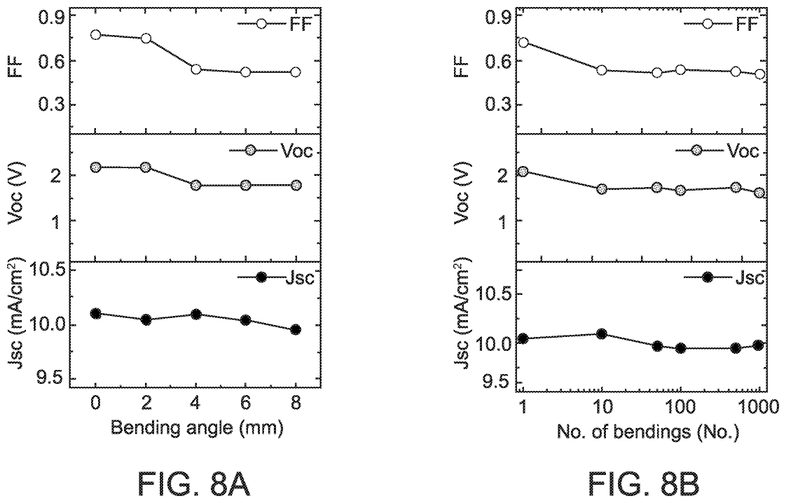

The photoelectrochemical device was also tested for its flexibility and bendability, the results of which are illustrated in the graphs of FIGS. 8A and 8B. This flexibility and bendability was achieved using a 50 μm thick nickel substrate, whereas conventional photoelectrochemical devices use a thick, non-flexible gallium arsenide substrate. As illustrated, the Jsc showed little change (less than a 10% overall variance) at various bending angles. In contrast, there is an enormous drop in the Voc and fill-factor (FF) after the radius of curvature exceeds 2 mm. This drop-off in Voc and fill-factor, particularly with the higher bending angles, can be attributed to the higher strain within the functional layers, and partial damage to the nickel substrate and the finger contacts.

FIG. 8B illustrates the results of repeated bendings to a curvature of 8 mm. As illustrated, the Jsc is constant after 1000 cycles of bending, demonstrating the sturdiness and robustness of the photoelectrochemical device. In contrast, the Voc falls from 2.1 V to 1.78 V and the fill-factor falls from 0.77 to 0.51 after two bending cycles and remains mostly constant up to 1,000 bending cycles. This demonstrates that even after high bending angels (i.e., 8 mm in this example) and a large number of cycles, the photoelectrochemical device exhibits the Voc of 1.78 V with high current density and could be employed for unassisted water splitting, although the operating potential is significantly reduced.

The photoelectrochemical device described above acts as a photoanode and requires an external cathode in order to perform unassisted water splitting. Exemplary embodiments can also include a monolithic water splitting device, which does not require an external cathode, examples of which are illustrated in FIGS. 9A and 9B. A monolithic water splitting device is particularly advantageous because it does not require any external connections or wires, which can become dislodged or tangled in certain water splitting environments.

As illustrated in FIG. 9A, a monolithic water splitting device 900A includes a first metallic electrocatalyst 902, which is formed on a substrate 905. In an embodiment, the first metallic electrocatalyst 902 assists with water oxidation reaction and can be comprised of atomic layer deposited nickel oxide (NiOₓ) having a thickness of, for example, 50 nm. The substrate 905 can be comprised of, for example, nickel or any other metallic material that can protect the device 902A from the electrolyte in which it will be operated.

A first ohmic contact layer 910 adjoins the substrate 905, and a tandem photoabsorber 915 adjoins the first ohmic contact layer 910. In an embodiment, the tandem photoabsorber is comprised of, for example, III-V materials, such as a gallium arsenide bottom photoabsorber 915A and an indium gallium phosphide top photoabsorber 915B. A second ohmic contact layer 920 adjoins the tandem photoabsorber 915 and a second metallic electrocatalyst 945 adjoins the second ohmic contact layer 920. In an embodiment, the second ohmic contact layer 920 is comprised of, for example, atomic layer deposited titanium oxide (TiOₓ) that also acts as a protection layer, and the second metallic electrocatalyst 945 can be comprised of, for example, atomic layer deposited platinum (Pt). Although embodiments have been described in which the first 902 and second 945 metallic electrocatalysts are formed using atomic layer deposition, these can be formed using other techniques, such as electrochemical deposition.

The water splitting device 900A is monolithic and thus, unlike the embodiments described above, does not require an external counter electrode. Accordingly, the monolithic water splitting device is able to use absorbed light to convert water into hydrogen and oxygen, which is why this type of structure is sometimes referred to as an artificial leaf.

The monolithic water splitting device 900A can be formed in a similar manner to the discussion above in connection with FIGS. 2 and 3A-3D—specifically using an epitaxial lift-off technique to first remove the tandem junction from a rigid substrate on which it is initially formed.

It will be appreciated that one problem with conventional monolithic water splitting devices is the lack of efficient transportation of charge carriers to the electrodes, which requires access to both sides of the device. The monolithic water splitting device 900A, however, permits access to both the light absorbing side (i.e., the side with the second metallic electrocatalyst 945 acting as a photocathode) and the side with the first metallic contact layer 905, which acts as an anode, and in one embodiment is comprised of nickel.

It may be desirable to evaluate the performance of the monolithic water splitting device of FIG. 9A, in which case additional layers are provided on the device, as illustrated in FIG. 9B. Specifically, as illustrated in FIG. 9B, a conductive layer 907 is interposed between the substrate 905 and the first ohmic contact layer 910 and a finger electrode 923 is arranged on top of the second ohmic contact layer 920. The conductive layer 907 can be formed on the first ohmic contact layer 910 prior to forming the substrate 905 in step 210. In an embodiment, the conductive layer 907 can be, for example, gold-beryllium (AuBe) deposited by an electron beam. The finger electrode 923 can be formed after the rigid substrate is removed in step 215. In an embodiment, the finger electrode 923 can be, for example, gold (Au) deposited by an electron beam.

In order to confirm the ability of the monolithic water splitting device to successfully perform water splitting, the electrocatalytic overpotential (η_{HER}/η_{OER}) values for platinum/platinum (Pt/Pt), platinum/ruthenium oxide (RuOₓ), and platinum/nickel oxide (Pt/NiOₓ) were analyzed in an electrolyte of 1 M KOH(aq). The analysis demonstrated that the total potential required to drive unassisted water splitting is 2.03 V for Pt/Pt, 1.78 for Pt/RuOₓ and 1.92 V for Pt/NiOₓ, which demonstrates that platinum and nickel oxide catalysts employed in the monolithic water splitting device described above can drive the unassisted reaction with less the potential of 1.92 V.

The monolithic water splitting device 900B illustrated in FIG. 9B was evaluated in an electrolyte of 1.0 M KOH to assess its performance. After 30 minutes of operation and collection time, the average volume of the gases was calculated to be ˜0.41 μl/s of H₂ and ˜0.18 μl/s of O₂. It should be noted that the gases evolved with the monolithic water splitting device 900B is much less than the gases evolved by employing an externally wired two electrode arrangement. The reduction in the efficiency could be due to the ohmic loss in potential due to the poor charge carrier transport in the electrolyte and the poor conductivity of surface protection layer (TiOₓ), which has been previously reported to reduce the photocurrent density of photoelectrodes in various electrolytes. The efficiency can be improved by optimizing the atomic layer deposited titanium oxide (TiOₓ).

The disclosed embodiments provide photoelectrochemical device, monolithic water splitting device, and methods of production. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

What is claimed is:

1. A photoelectrochemical device (100A, 100B, 900A, 900B) comprising:
a substrate (105, 905) comprising a metallic electrocatalyst;
a first ohmic contact layer (110, 910) arranged on the substrate (105, 905);
a tandem photoabsorber (115, 915) arranged on the first ohmic contact layer (110, 910);
a second ohmic contact layer (120, 920) arranged on the tandem photoabsorber (115, 915); and
a protective layer (125, 925) arranged on the second ohmic contact layer (120, 1120),
wherein the substrate (105, 905) is comprised of a different material than the tandem photoabsorber (115, 915).

2. The photoelectrochemical device of claim 1, wherein the tandem photoabsorber comprises first and second photoabsorbers, each comprising group III and group V materials.

3. The photoelectrochemical device of claim 2, wherein the first photoabsorber comprises gallium arsenide and the second photoabsorber comprises indium gallium phosphide.

4. The photoelectrochemical device of claim 1, further comprising:
a metallic electrocatalyst physically separated from and electrically coupled to the second ohmic contact.

5. The photoelectrochemical device of claim 1, wherein the metallic electrocatalyst of the substrate is nickel or nickel oxide.

6. The photoelectrochemical device of claim 1, wherein the substrate is flexible.

7. The photoelectrochemical device of claim 1, further comprising:
a second metallic electrocatalyst on which the substrate is arranged; and
a third metallic electrocatalyst arranged on the second ohmic contact,
wherein the photoelectrochemical device is a monolithic photoelectrochemical device that does not include external connections or wires.

8. The photoelectrochemical device of claim 7, wherein the second electrocatalyst comprises nickel oxide.

9. The photoelectrochemical device of claim 7, wherein the third electrocatalyst comprises platinum.

10. A method, comprising:
providing (205) a tandem photoabsorber (315) supported on a first side by a rigid substrate (340);
forming (210) a substrate (305) on a second side of the tandem photoabsorber (315);
removing (215) the rigid substrate (340) from the first side of the tandem photoabsorber (315); and
forming (220) a protective layer (325) on the first side of the tandem photoabsorber (315).

11. The method of claim 10, further comprising:
removing the photoelectrochemical device from the substrate using epitaxial lift-off.

12. The method of claim 10, further comprising:
forming a first electrocatalyst on the substrate.

13. The method of claim 12, further comprising:
forming a second electrocatalyst on the first side of the tandem photoabsorber prior to forming the protective layer.

14. The method of claim 13, further comprising:
forming the first and second electrocatalysts using atomic layer deposition.

15. A monolithic water splitting device, comprising:
a first metallic electrocatalyst (902);
a metallic substrate (905) arranged on the first metallic electrocatalyst (902);
a first ohmic contact layer (910) adjoining the metallic substrate (905);
a tandem photoabsorber (915) comprising group III and group V materials and adjoining the first metallic contact layer (905);
a second ohmic contact layer (920) adjoining the tandem photoabsorber (915); and
a second metallic electrocatalyst (945) adjoining the second ohmic contact layer (920).

16. The monolithic water splitting device of claim 15, wherein the tandem photoabsorber comprises a first photoabsorber comprising gallium arsenide and a second photoabsorber comprising indium gallium phosphide.

17. The monolithic water splitting device of claim 15, wherein the first metallic electrocatalyst and the metallic substrate comprise nickel.

18. The monolithic water splitting device of claim 15, wherein the second metallic electrocatalyst comprises titanium and platinum.

19. The monolithic water splitting device of claim 15, wherein the monolithic water splitting device is configured to perform unassisted water splitting without external connections or wires.

20. The monolithic water splitting device of claim 15, wherein
the first metallic electrocatalyst is arranged on a first side of the monolithic water splitting device,
the second metallic electrocatalyst is arranged on a second side of the monolithic water splitting device,
the first side of the monolithic water splitting device is a photocathode configured to absorb light, and
the second side of the monolithic water splitting device is an anode.
